(19) United States
(12) Patent Application Publication
(10) Pub. No.: US 2026/0006956 A1
(43) Pub. Date: Jan. 1, 2026

(54) LEAD FRAME STRUCTURES FOR REFLOW MITIGATION IN LIGHT-EMITTING DIODE (LED) PACKAGES

(71) Applicant: CreeLED, Inc., Durham, NC (US)

(72) Inventors: Michael Check, Holly Springs, NC (US); Robert David Schmidt, Wake Forest, NC (US)

(21) Appl. No.: 18/754,541

(22) Filed: Jun. 26, 2024

(51) Int. Cl. H01L 33/62; H01L 25/075; H01L 33/44; H01L 33/48; H01L 33/56

(52) U.S. Cl. CPC H10H 20/857; H01L 25/0753; H10H 20/84; H10H 20/8506; H10H 20/854

(57) ABSTRACT

Light-emitting diode (LED) devices and more particularly lead frame structures for reflow mitigation in LED packages are disclosed. Lead frame structures include various features positioned within a recess of a package housing and proximate mounting areas of LED chips within the recess. The features may include nonplanar shapes relative to a floor of the recess that promote increased adhesion with an encapsulant in the recess while also mitigating effects of reflow when the package is later bonded at a device level. Exemplary nonplanar shapes include portions of leads that extend upward into the recess and/or portions of leads that extend downward below the floor of the recess. The features may be arranged in rows, as islands, or even as random structures along portions of the leads.

### FIELD OF THE DISCLOSURE

The present disclosure relates to light-emitting diode (LED) devices, and more particularly to lead frame structures for reflow mitigation in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to lead frame structures for reflow mitigation in LED packages. Lead frame structures include various features positioned within a recess of a package housing and proximate mounting areas of LED chips within the recess. The features may include nonplanar shapes relative to a floor of the recess that promote increased adhesion with an encapsulant in the recess while also mitigating effects of reflow when the package is later bonded at a device level. Exemplary nonplanar shapes include portions of leads that extend upward into the recess and/or portions of leads that extend downward below the floor of the recess. The features may be arranged in rows, as islands, or even as random structures along portions of the leads.

In one aspect, an LED package comprises: a housing forming a recess with a recess floor; a lead frame structure within the housing; one or more LED chips positioned on the lead frame structure and at the recess floor; and a plurality of features of the lead frame structure, the plurality of features being nonplanar relative to the recess floor and positioned laterally adjacent to mounting areas of the one or more LED chips. In certain embodiments: the one or more LED chips comprise a first LED chip; and the lead frame structure comprises a first lead and a second lead, and the first LED chip is flip-chip mounted to the first lead and the second lead with a chip bonding material. In certain embodiments: the first lead and the second lead each comprise a first region that includes at least one feature of the plurality of features and a second region where the first LED chip is flip-chip mounted. In certain embodiments, the second region is devoid of the plurality of features. In certain embodiments, at least one other feature of the plurality of features is in the second region. In certain embodiments: a first feature of the plurality of features is part of the first lead; the first feature extends parallel to the recess floor along a first plane in the recess; and the first LED chip is mounted to the first lead along a second plane that is closer to the recess floor than the first plane. In certain embodiments, the first lead extends from the first plane to the second plane in an angled manner. The LED package may further comprise: a coating on the first lead and the second lead, the coating extending to a third plane in the recess such that the first plane is between the third plane and the second plane; and an encapsulant in the recess such that the coating is between the encapsulant and the first lead and the coating is between the encapsulant and the second lead. In certain embodiments, the coating comprises an epoxy material.

The LED package may further comprise an encapsulant in the recess, wherein the encapsulant forms an interface with at least a portion of the plurality of features. In certain embodiments, the encapsulant comprises an epoxy material. In certain embodiments, the plurality of features extend into the recess and below the recess floor. In certain embodiments, a portion of the encapsulant is positioned between a portion of the plurality of features and the recess floor. In certain embodiments, a portion of the housing is positioned between another portion of the plurality of features and the recess floor.

In certain embodiments, the one or more LED chips are mounted to the lead frame structure with a chip bonding material, and the plurality of features form a raised barrier configured to confine the chip bonding material. In certain embodiments, the plurality of features form a plurality of rows on the lead frame structure. In certain embodiments, the plurality of features form a plurality of islands of the lead frame structure. In certain embodiments, the plurality of features form a grid of the lead frame structure. In certain embodiments, the plurality of features form a plurality of indentations of the lead frame structure. In certain embodiments, at least one feature of the plurality of features forms a primary shape with at least one secondary shape formed along a side of the primary shape. In certain embodiments, at least two features of the plurality of features form a wicking cavity between top surfaces of the at least two features and underlying portions of the lead frame structure.

In another aspect, a lighting device comprises a board; and a light-emitting diode (LED) package mounted on the board, the LED package comprising: a housing forming a recess with a recess floor; a lead frame structure within the housing; one or more LED chips positioned on the lead frame structure and at the recess floor; and a plurality of features of the lead frame structure, the plurality of features being nonplanar relative to the recess floor and positioned laterally adjacent to mounting areas of the one or more LED chips. The LED package may further comprise signal processing and driver circuitry electrically coupled to the board, wherein the board is a printed circuit board (PCB) of an LED display. In certain embodiments, the LED package is coupled with the board by solder material between the lead frame structure and the board. In certain embodiments, the one or more LED chips comprises at least three LED chips in a linear arrangement. In certain embodiments, the one or more LED chips are mounted to the lead frame structure with a chip bonding material; the LED package is mounted to the board with a package bonding material; and the plurality of features form a raised barrier configured to confine the chip bonding material during formation of the package bonding material.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package that includes a lead frame structure collectively formed by a plurality of leads, a body or housing that encases a portion of the lead frame structure, and a recess formed by the housing according to principles of the present disclosure.

FIG. 1B is a cross-sectional view of the LED package of FIG. 1A taken along the sectional line 1B-1B of FIG. 1A.

FIG. 1C is a cross-sectional view of a portion of an LED device that includes the LED package of FIG. 1B bonded to a board.

FIG. 2 is a cross-sectional view of an LED package that is similar to the LED package of FIG. 1B, except the features are also present along mounting areas for the LED chips.

FIG. 3 is a cross-sectional view of an LED package that is similar to the LED package of FIG. 1B for embodiments where the features also extend below the recess floor.

FIG. 4 is a cross-sectional view of an LED package that is similar to the LED package of FIG. 3 for embodiments where one or more of the features extend below the recess floor in a manner where portions of the housing may not be present between the features and the recess floor.

FIG. 5 is a cross-sectional view of an LED package that is similar to the LED package of FIG. 1B for embodiments where the features are raised into the recess on either side of the LED chip and define a depression in the lead frame structure where the LED chip is mounted.

FIG. 6 is a cross-sectional view of an LED package that is similar to the LED package of FIG. 5 for embodiments that further include a coating on the leads.

FIG. 7 is a cross-sectional view of an exemplary lead of a lead frame structure where the features are formed with rounded shapes that protrude upward from the remainder of the lead.

FIG. 8 is a cross-sectional view of the exemplary lead for embodiments where the features are formed with rounded shapes that protrude downward and into the lead.

FIG. 9 is a cross-sectional view of the exemplary lead for embodiments where the features are formed with angled shapes that protrude downward and into the lead.

FIG. 10 is a top view of the exemplary lead for embodiments where the features form rows across the lead.

FIG. 11 is a top view of the exemplary lead for embodiments where the features form a plurality of islands across the lead.

FIG. 12 is a top view of the exemplary lead for embodiments where the features form another plurality of islands across the lead.

FIG. 13 is a top view of the exemplary lead for embodiments where the features form intersecting rows across a first region.

FIG. 14 is a cross-sectional view of the exemplary lead for embodiments where the features form combinations of primary shapes with secondary shapes formed thereon.

FIG. 15 is a cross-sectional view of the exemplary lead for embodiments where the features form a random pattern along the lead.

FIG. 16 is a cross-sectional view of the exemplary lead for embodiments where the features form one or more wicking cavities between top surfaces of the features and remaining portions of the underlying lead.

FIG. 17 is a cross-sectional view of an LED package that is similar to the LED package of FIGS. 1B and 1C for indoor applications.

FIG. 18 is a cross-sectional view of an LED package that is similar to the LED package of FIG. 3 for indoor applications.

FIG. 19 is a cross-sectional view of an LED package that is similar to the LED package of FIG. 4 for indoor applications.

FIG. 20 is a cross-sectional view of an LED package that is similar to the LED package of FIG. 6 for indoor applications.

FIG. 21 is a schematic diagram of a portion of an LED display screen, that is, for example, an indoor and/or outdoor screen comprising, in general terms, a display panel including a driver printed circuit board (PCB) carrying a large number of surface-mount devices (SMDs) arranged in rows and columns, each SMD defining a pixel.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to lead frame structures for reflow mitigation in LED packages. Lead frame structures include various features positioned within a recess of a package housing and proximate mounting areas of LED chips within the recess. The features may include nonplanar shapes relative to a floor of the recess that promote increased adhesion with an encapsulant in the recess while also mitigating effects of reflow when the package is later bonded at a device level. Exemplary nonplanar shapes include portions of leads that extend upward into the recess and/or portions of leads that extend downward below the floor of the recess. The features may be arranged in rows, as islands, or even as random structures along portions of the leads.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SIC), silicon, aluminum nitride (AlN), and GaN.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to multiple-chip LED packages where multiple LED chips are arranged within a common recess and sometimes beneath a common lens of an LED package. In certain embodiments, LED packages may include red, green, and blue LED chips such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphores), such as phosphors, such that at least some of the light from the LED chip is absorbed by the one or more lumiphores and is converted to one or more different wavelength spectra according to the characteristic emission from the one or more lumiphores. In this regard, at least one lumiphore receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphores (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support member, such as a lead frame structure. LED packages may include lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

In conventional LED packages, encapsulant materials are provided that at least partially fill a recess in the housing, thereby encapsulating one or more LED chips and associated electrical connections that are otherwise exposed within the recess. In LED packages with lead frame structures, it is common to have portions of lead frame structures accessible as mounting locations and electrical connections for LED chips. In certain aspects, LED chips may be mounted by way of flip-chip mounting. In such arrangements, an exemplary LED chip may be flip chip mounted to two leads of a lead frame structure. For example, an anode of the LED chip is bonded and electrically connected to one lead and a cathode of the LED chip is bonded and electrically connected to another lead of the lead frame structure. The LED chip may be bonded by way of a solder attach or other direct die attach material that is between the leads and the corresponding anode and cathode of the LED chip.

When the LED package is later assembled in an end use product, such as an LED display or a lighting fixture, anode and cathode connections of the LED package are also bonded. Such bonding may mount the LED package to another surface, such as a printed circuit board of an LED display or an LED lighting device. The LED package may be subject to high temperatures associated with package bonding and the previous bonding materials used to bond the LED chip to the lead frame structure may be subjected to reflow. In the example of solder attach, the solder material may reflow and wick and/or spread along the lead frame structure. In this regard, the solder material may travel away from LED chip bonding areas to other portions of the lead frame structure that is accessible within the housing recess. Associated problems include forming rough surfaces of reflow material within the recess that may create light unwanted scattering surfaces that impact color mixing and/or far field patterns of light emissions. Other problems associated with solder reflow include too much solder material traveling away from intended bonding locations, thereby decreasing mechanical and/or electrical integrity of bonding between the LED chip and lead frame structure. In such instances, decreased performance and/or product failure may be related to poor electrical connections for the LED chip or reduced thermal conductivity between the LED chip and the lead frame structure.

Certain LED packages are designed for use in outdoor applications that provide increased exposure to various environmental conductions. Epoxy based materials are typically used as encapsulant materials for outdoor applications since they provide increased protection from environmental ingress. However, interfaces between epoxy materials and die attach materials for LED chips may have reduced adhesion within the LED package as compared with silicone based encapsulants. In this regard, problems associated with solder reflow may be exacerbated in LED packages with epoxy-based encapsulants.

Aspects of the present disclosure relate to lead frame structures that mitigate problems associated with solder reflow. In certain embodiments, lead frame structures are provided within package recesses with features that improve anchoring of encapsulant materials to leads, provide physical barriers that control and/or confine solder wicking, and/or separate planes where encapsulant materials adhere to leads from planes where bonding materials attach LED chips to leads. As used throughout, such features may also be referred to as adhesion and/or confinement features. Exemplary lead frame structures include various localized features, such as raised projections and/or indentations of portions of leads within housing recesses. Indentations may provide raised barriers that provide up-hill resistance for solder reflow. Indentations of leads may provide regions that control where solder reflow may travel. Accordingly, lead frame features that mitigate solder reflow and provide improved encapsulant adhesion are provided within housing recesses and are therefore positioned within light paths of LED emissions that may reflect along housing recesses before exiting LED packages.

Exemplary shapes for such localized features include raised ridges, hillocks, raised cones, valleys, divots, indentations, grooves, raised or indented thatching patterns, and/or bending portions among others. The features may be integrally formed with the lead frame structure, such as when leads are initially formed. The features may also be formed with a subsequent deformation process, such as stamping and/or bending of the leads. In alternative embodiments, the features may be separately formed and later adhered to the lead frame structure.

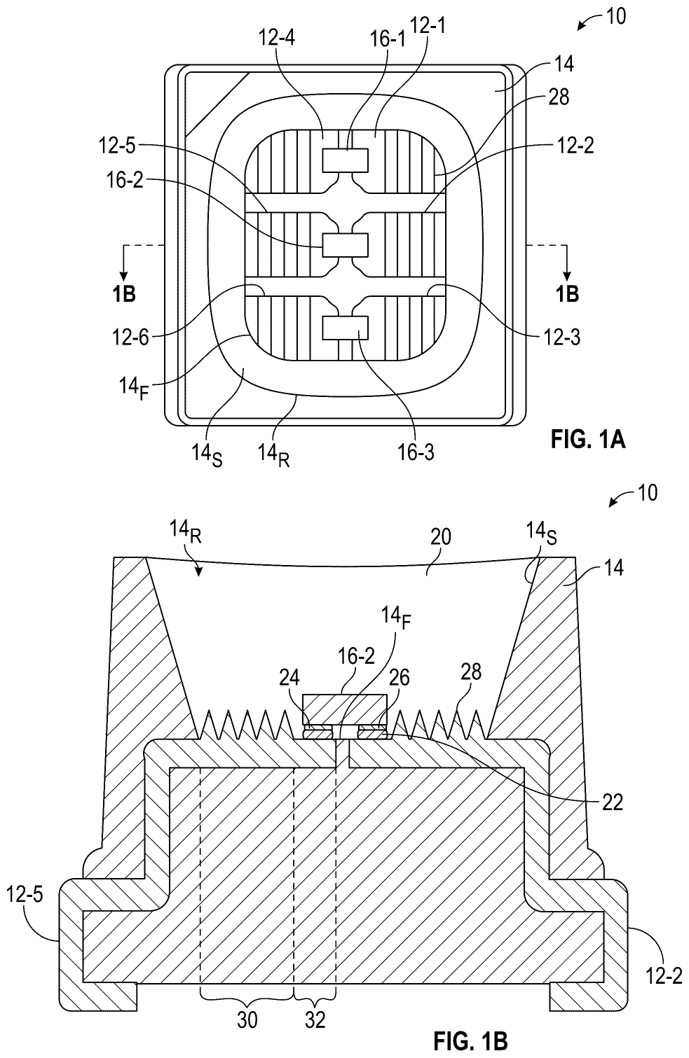

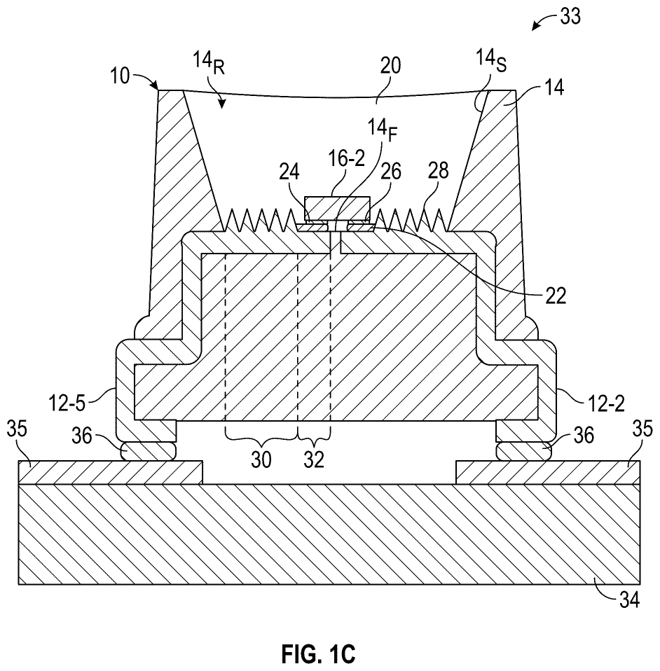

FIG. 1A is a top view of an LED package 10 that includes a lead frame structure collectively formed by a plurality of leads 12-1 to 12-6, a body or housing 14 that encases a portion of the lead frame structure, and a recess 14R formed by the housing 14. FIG. 1B is a cross-sectional view of the LED package 10 of FIG. 1A taken along the sectional line 1B-1B of FIG. 1A. The LED package 10 includes LED chips 16-1 to 16-3 that are flip-chip mounted on corresponding pairs of the leads 12-1 to 12-6 and an encapsulant 20 that at least partially fills the recess 14R, thereby covering the LED chips 16-1 to 16-3.

In certain aspects, each of the LED chips 16-1 to 16-3 may be configured to emit a different wavelength from the other LED chips. For example, the LED chip 16-1 may be configured to emit red light, the LED chip 16-2 may be configured to emit green light, and the LED chip 16-3 may be configured to emit blue light. While three LED chips 16-1 to 16-3 are illustrated, the principles disclosed herein are applicable to any number of LED chips within the LED package 10. The recess 14R may include a recess floor 14F and one or more recess sidewalls 14s. The leads 12-1 to 12-6 may be arranged to extend through the housing 14 and a portion of the leads 12-1 to 12-6 may be arranged along or otherwise exposed at the recess floor 14F within the recess 14R.

As best illustrated in FIG. 1B, the leads 12-2, 12-5 form at least two bends within the housing 14, thereby providing increased distance for any harmful moisture ingress. While only the leads 12-2, 12-5 are visible in the cross-section of FIG. 1B, it is understood all of the leads 12-1 to 12-6 may be formed with the same or similar shape. The leads 12-2, 12-5 are accessible along the recess floor 14F for electrically connecting with the LED chips 16-1 to 16-3. The LED chips 16-1 to 16-3 may be attached to corresponding pairs of leads 12-1 to 12-6 by way of a chip bonding material 22, such as a solder attach material, between anode and cathode pads 24, 26 of the LED chips 16-1 to 16-3 and the corresponding leads 12-1 to 12-6. As described above, after the LED package 10 is fabricated, the LED package 10 may be subsequently bonded to another surface, such as within an LED display or other lighting device. In this manner, portions of the leads 12-1 to 12-6 that extend along and outside a bottom of the housing 14 are bonded with additional bonding materials. During this process, the chip bonding material 22 for the LED chips 16-1 to 16-3 may be subject to reflow and travel along portions of the leads 12-1 to 12-6.

According to aspects of the present disclosure, the leads 12-1 to 12-6 include features 28 within the recess 14R that improve adhesion with the encapsulant 20 and/or form confinement features that mitigate reflow of the chip bonding material 22. In certain embodiments, the features 28 are formed in a first region 30 of the leads 12-1 to 12-6 that is laterally adjacent to the LED chips 16-1 to 16-3. In this manner, the first region 30 defines an encapsulant attach region where interfaces between the encapsulant 20 and the leads 12-1 to 12-6 are present. A second region 32 of the leads 12-1 to 12-6 defines die attach regions wherein the LED chips 16-1 to 16-3 are flip-chip mounted to the leads 12-1 to 12-6. In this manner, the second region 32 defines a bonding material attach region where the chip bonding material 22 is present after the LED chips 16-1 to 16-3 are mounted. In FIG. 1B, the features 28 form raised features that extend upward from the recess floor 14F and into the recess 14R. In certain embodiments, the features 28 are nonplanar relative to the recess floor 14F (i.e., a plane thereof) and positioned laterally adjacent to mounting areas of the LED chips 16-1 to 16-3. Accordingly, the features 28 provide increased surface area in a nonplanar manner for enhanced adhesion with the encapsulant 20. In the event the encapsulant 20 does start to detach, the presence of the features 28 may limit detachment to localized areas of the leads 12-1 to 12-6. Additionally, the features 28 form a raised barrier that confines areas where the chip bonding material 22 may reflow, thereby keeping the chip bonding material 22 within or near the second region 32. As illustrated, the second region 32 may be devoid of the features 28 in certain embodiments, thereby providing planar mounting surfaces for the LED chips 16-1 to 16-3.

FIG. 1C is a cross-sectional view of a portion of an LED device 33 that includes the LED package 10 of FIG. 1B bonded to a board 34. The board 34 may embody a printed circuit board (PCB) or panel for embodiments where the LED device is an LED display, a lighting device, or a module for a display or lighting device, among others. As illustrated, the leads 12-2, 12-5 are bonded to corresponding electrical connections 35 of the board 34 by way of a package bonding material 36. The electrical connections 35 may embody traces or pads of the board 34. In certain embodiments, the package bonding material 36 may be the same material as the chip bonding material 22, such as a solder material, although other materials may also be used. During bonding of the LED package 10 to the board 34, elevated bonding temperatures for the package bonding material 36 may be sufficient to cause reflow of the chip bonding material 22. As illustrated in FIG. 1C, the presence of the features 28 provides a physical barrier that effectively confines the chip bonding material 22 to smaller areas of the leads 12-2, 12-6.

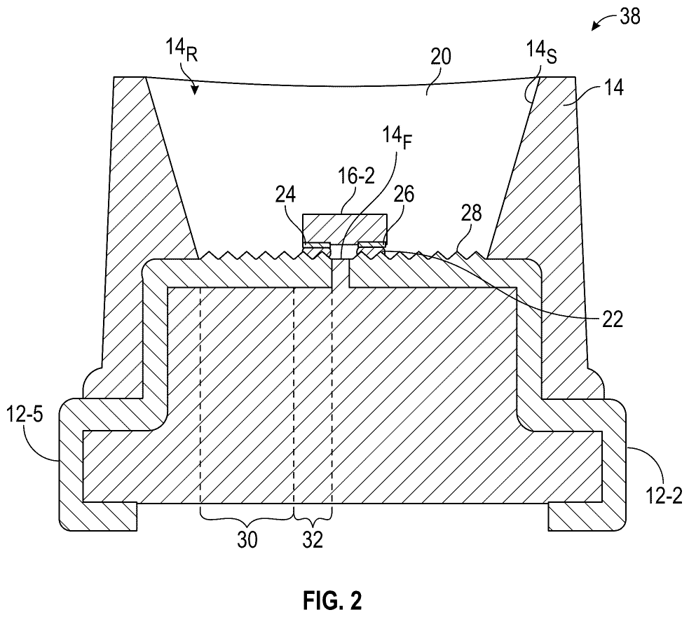

FIG. 2 is a cross-sectional view of an LED package 38 that is similar to the LED package 10 of FIG. 1B, except the features 28 are also present along mounting areas for the LED chips 16-1 to 16-3. As illustrated, the features 28 are present in both the first region 30 and the second region 32. In this manner, the chip bonding material 22 may fill portions of the nonplanar structure of the features 28 and may be more resistant to lateral spreading during reflow.

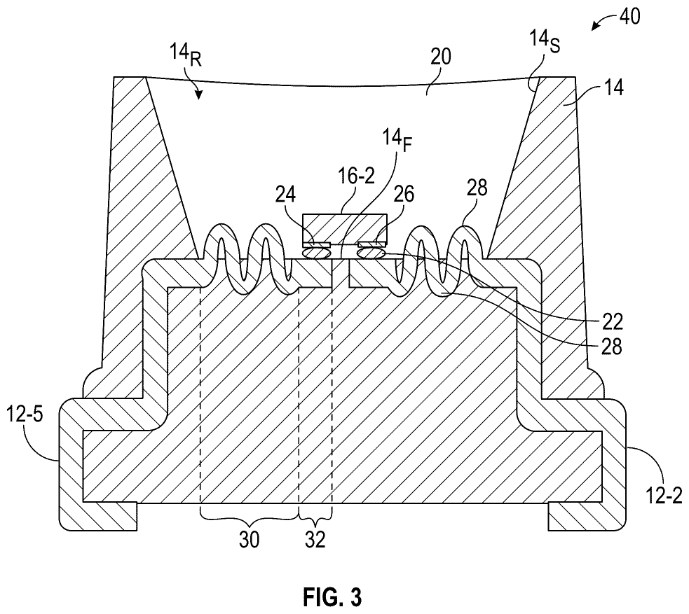

FIG. 3 is a cross-sectional view of an LED package 40 that is similar to the LED package 10 of FIG. 1B for embodiments where the features 28 also extend below the recess floor 14F. As illustrated, the features 28 of the leads 12-2, 12-5 may extend or curve upward into the recess 14R and extend or curve downward below the recess floor 14F. In certain embodiments, a portion of the encapsulant 20 is positioned between a portion of one or more of the features 28 and the recess floor 14F within the recess 14R. Additionally, portions of the housing 14 may be positioned between other portions of one or more of the features 28 and the recess floor 14F. In such an arrangement, the features 28 may provide enhanced anchoring with the housing 14 and the encapsulant 20. In certain embodiments, forming the features 28 extending above and below the recess floor 14F may reduce the impact of any moisture ingress by providing increased distance for moisture ingress to travel. In combination with the multiple bends for each lead 12-2, 12-5 within the housing 14, the LED package 40 may provide increased resistance to moisture ingress.

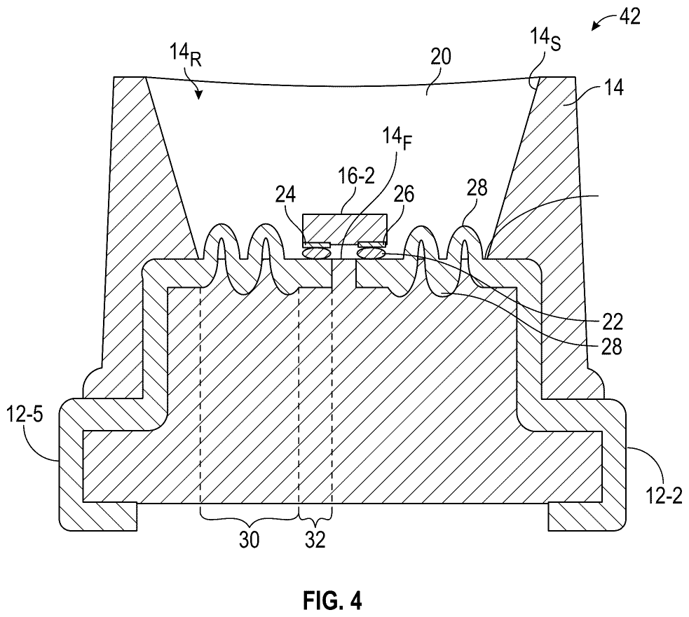

FIG. 4 is a cross-sectional view of an LED package 42 that is similar to the LED package 40 of FIG. 3 for embodiments where one or more of the features 28 extend below the recess floor 14F in a manner where portions of the housing 14 may not be present between the features 28 and the recess floor 14F. For example, in FIG. 4, each of the leads 12-2, 12-5 includes at least one feature 28 that extends below the recess floor 14F in a continuous manner so that portions of the housing 14 may not fill gaps directly above the features 28 in a perpendicular direction relative to the recess floor 14F. In this manner, the leads 12-2, 12-5 may exhibit increased mechanical stability for facilitating improved flip-chip mounting of the LED chip 16-2. Portions of the housing 14 may still be present between adjacent features 28 below the recess floor 14F for enhanced anchoring.

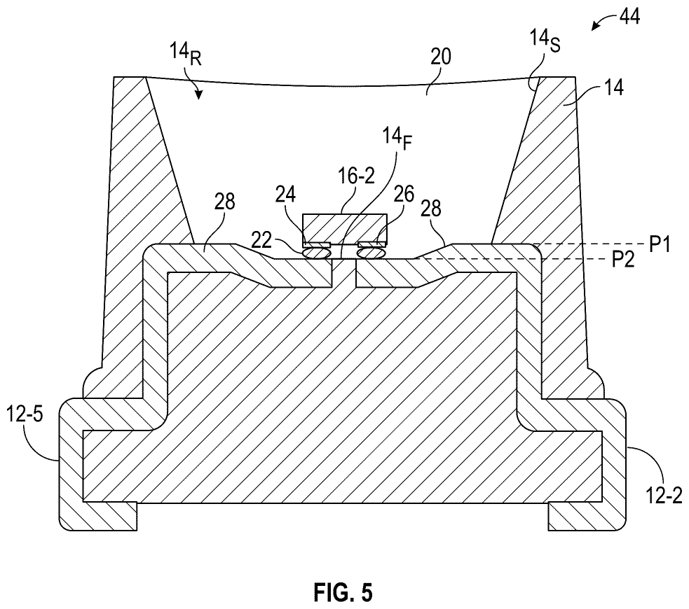

FIG. 5 is a cross-sectional view of an LED package 44 that is similar to the LED package 10 of FIG. 1B for embodiments where the features 28 are raised into the recess 14R on either side of the LED chip 16-2 and define a depression in the lead frame structure where the LED chip 16-2 is mounted. As illustrated, the features 28 embody a raised portion of each of the leads 12-2, 12-5 that may extend parallel to the recess floor 14F in a first plane P1 in the recess 14R. A depression of the leads 12-2, 12-5 is defined between the features 28 along a second plane P2 that is closer to the recess floor 14F than the first plane P1. The LED chip 16-2 is mounted to portions of the leads 12-2, 12-5 along the second plane P2. In certain embodiments, the second plane P2 may correspond with a plane of the recess floor 14F. In certain embodiments, portions of the features 28 may form in an angled manner as the leads 12-2, 12-5 extend from the first plane P1 to the second plane P2. As with other embodiments, the features 28 may form raised barriers for confining the chip bonding material 22 during reflow.

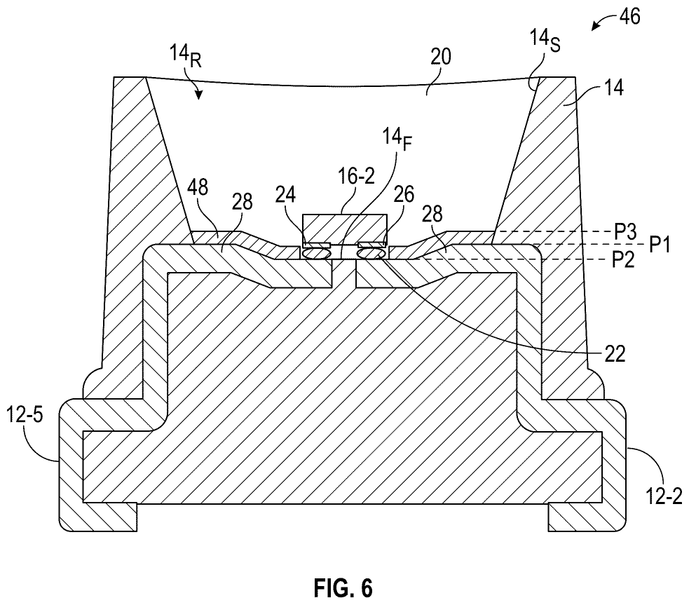

FIG. 6 is a cross-sectional view of an LED package 46 that is similar to the LED package 44 of FIG. 5 for embodiments that further include a coating 48 on the leads 12-2, 12-5. The coating 48 may be formed on portions of the leads 12-2, 12-5 that are accessible within the recess 14R. The coating 48 may form a physical blocking layer that effectively increases a height of a raised barrier from the features 28 to provide further confinement of the chip bonding material 22 during reflow. As illustrated, the coating 48 may extend to and/or parallel with a third plane P3 that is higher than the first plane P1. In certain embodiments, a material of the coating 48 may embody a solder mask, a light-altering material such as white fill for improved reflectivity, silicone, polyphthalamide (PPA), polycyclohexylenedimethylene terephthalate (PCT), or an extension of material of the housing the housing 14. In other embodiments, the coating 48 may embody a similar material as the encapsulant 20, such as epoxy. In still further embodiments, the coating 48 may comprise any of the materials listed above with a loading of embedded light-altering particles, such as particles of TiO₂, Al₂O₃, SiO₂, carbon, silicon, or metals. When both the coating 48 and the encapsulant 20 comprise epoxy, constituent ratios of the coating 48, such as epoxy material ratios with diffusers or other ingredients, may be different between the coating 48 and the encapsulant 20. For example, the constituent ratios of the coating 48 may tailored to provide the coating 48 with improved adhesion with the leads 12-2, 12-5, improved flexibility, increased resistance to thermal stress, increased resistance to cracking, and/or different optical properties relative to the encapsulant 20.

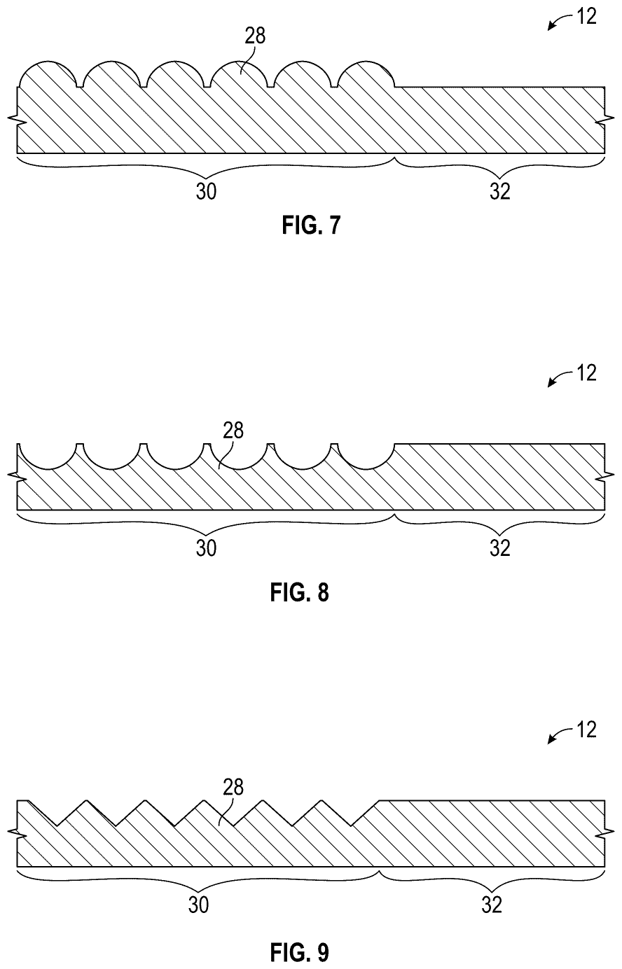

FIGS. 7 to 16 illustrate various alternative structures for the features 28 of a lead frame structure for mitigating reflow of chip bonding materials as described above. Any of the structures illustrated in FIGS. 7 to 16 may be implemented for the features in any of the embodiments described above for FIGS. 1A to 6. In each of FIGS. 7 to 16, the features 28 are illustrated along just the first region 30, and the second region 32 corresponds with a portion of the lead 12 for providing an electrical connection with an LED chip. In alternative configurations, any of the features 28 as illustrated in FIGS. 7 to 16 may also extend into the second region 32 as described above for FIG. 2.

FIG. 7 is a cross-sectional view of an exemplary lead 12 of a lead frame structure where the features 28 are formed with rounded shapes that protrude upward from the remainder of the lead 12. In certain embodiments, the features 28 may form circular or half-circular cross-sectional shapes. The features 28 with rounded top surfaces may form elongated rows or individual islands along the lead 12 for mitigating effects of reflow.

FIG. 8 is a cross-sectional view of the exemplary lead 12 for embodiments where the features 28 are formed with rounded shapes that protrude downward as indentations into the lead 12. The features 28 may form elongated rows of indentations or individual regions of indentations such as dimples along the lead 12 for mitigating effects of reflow. For example, the features 28 of FIG. 8 may form depressions or recesses of the lead 12 for collecting material during reflow.

FIG. 9 is a cross-sectional view of the exemplary lead 12 for embodiments where the features 28 are formed with angled shapes that protrude downward as indentations into the lead 12. In FIG. 9, the features 28 may form triangular cross-sectional shapes. The features 28 may form elongated rows of indentations or individual regions of indentations along the lead 12 for mitigating effects of reflow. As with FIG. 8, the features 28 of FIG. 9 may form depressions or recesses of the lead 12 for collecting material during reflow.

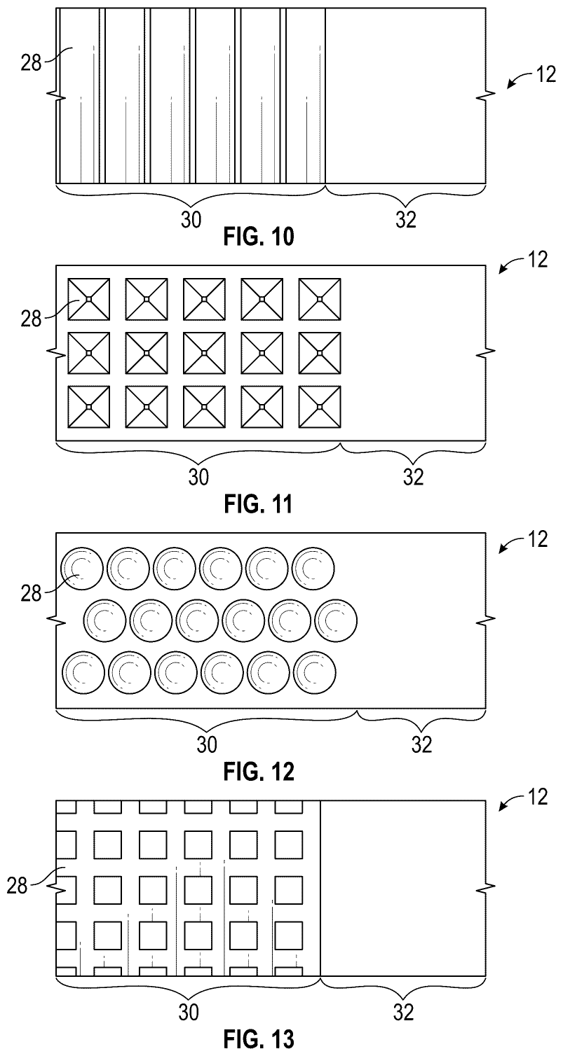

FIG. 10 is a top view of the exemplary lead 12 for embodiments where the features 28 form rows across the lead 12. As illustrated, the rows of the features 28 may be formed in a perpendicular manner with respect to a length of the lead 12. In this manner, if chip bonding material were to spread from the second region 32 during reflow, the features 28 effectively form raised walls in a direction perpendicular to a primary direction of reflow. In certain embodiments, the features 28 may form rows with curved surfaces in a manner similar to FIG. 3, 4, 7, or 8, or angled surfaces as illustrated in any of FIGS. 1B, 2, 5, 6, and 9. The features 28 may form a raised rows relative to the lead 12 or a recessed rows relative to lead 12.

FIG. 11 is a top view of the exemplary lead 12 for embodiments where the features 28 form a plurality of islands across the lead 12. The features 28 may form an array of pyramids across the first region 30 to form various barriers for reflow. The island structure may promote increased adhesion with the encapsulant (i.e., the encapsulant 20 of FIG. 1B) by providing further increased surface area therebetween. In certain embodiments, the features 28 form an array of pyramids that protrude upward from the lead 12. In other embodiments, the features 28 form an array of indentations having pyramid shapes that are recessed into the lead 12.

FIG. 12 is a top view of the exemplary lead 12 for embodiments where the features 28 form another plurality of islands across the lead 12. In FIG. 12, the features 28 may form an array of cones across the first region 30 to form various barriers for reflow. As with FIG. 11, the island structure of FIG. 12 may promote increased adhesion with the encapsulant (i.e., the encapsulant 20 of FIG. 1B) by providing further increased surface area therebetween. In certain embodiments, the features 28 form an array of rounded or circular features that protrude upward from the lead 12. In other embodiments, the features 28 form an array of indentations having rounded or circular shapes that are recessed into the lead 12.

FIG. 13 is a top view of the exemplary lead 12 for embodiments where the features 28 form intersecting rows across the first region 30. As illustrated, the intersecting rows of the features 28 may form a grid structure for mitigating reflow. The features 28 of the grid structure may have various shapes as described above, including curved surfaces in a manner similar to FIG. 3, 4, 7, or 8, or angled surfaces as illustrated in any of FIGS. 1B, 2, 5, 6, and 9. The features 28 may form a raised grid structure relative to the lead 12 or a recessed grid structure relative to lead 12.

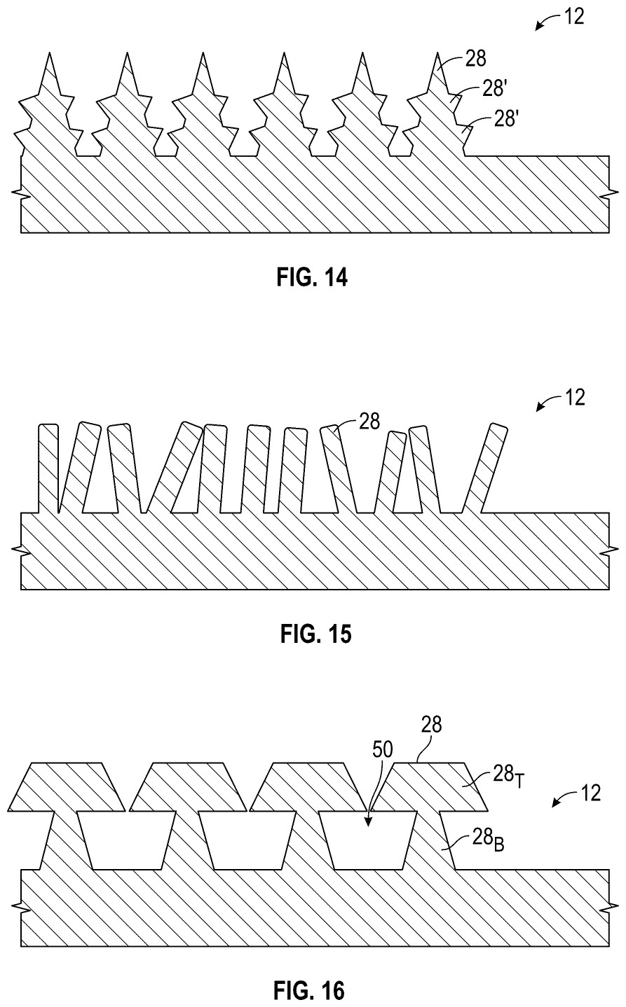

FIG. 14 is a cross-sectional view of the exemplary lead 12 for embodiments where the features 28 form combinations of primary shapes with secondary shapes formed thereon. By way of example, each feature 28 may have a primary shape with a generally triangular cross-section and one or more secondary shapes 28′ formed thereon, such as along one or more sides of the primary shape. In this manner, the secondary shapes 28′ provide additional surface area for enhanced adhesion and/or mitigation of reflow. In certain embodiments, the shape of the features 28 as illustrated in FIG. 14 may be referred to as having texture on texture (i.e., secondary shapes 28′ on primary shapes of the features 28).

FIG. 15 is a cross-sectional view of the exemplary lead 12 for embodiments where the features 28 form a random pattern along the lead 12. As illustrated, the distribution and/or orientation of features 28 need not be uniform to provide increased adhesion and/or reflow mitigation. By way of example, the features 28 in FIG. 15 form a random forest structure with protrusions extending at a variety of angles from the lead 12.

FIG. 16 is a cross-sectional view of the exemplary lead 12 for embodiments where the features 28 form one or more wicking cavities 50 between top surfaces of the features 28 and remaining portions of the underlying lead 12. As illustrated, each wicking cavity 50 may be formed by neighboring features 28. In this manner, top surfaces of the features 28 may form interfaces with the encapsulant 20 of FIG. 1B while any reflow of the chip bonding material 22 may be confined to the underlying wicking cavities 50. By way of example, the features 28 may form mushroom shapes with larger area top portions 28T and narrower base portions 28B connecting to the remainder of the lead 12. In certain embodiments, the top portions 28T may touch one another or be separated by relatively small gaps. When viewed from above, the top portions 28T may effectively mask the appearance of any reflow material to avoid reduction in reflectivity.

The embodiments described above with respect to FIGS. 1A to 6 are provided in the context of LED packages well suited for outdoor applications. As described above, such LED packages may include lead frame structures that bend multiple times within a corresponding housing to mitigate the effects of moisture ingress from a surrounding environment. However, the principles described above for the LED packages of FIGS. 1A to 6 and for the various configurations described for FIGS. 7 to 16 are applicable to LED packages configured for indoor use. In this manner, the principles described above are also applicable to lead frame structures that do not bend multiple times within a housing.

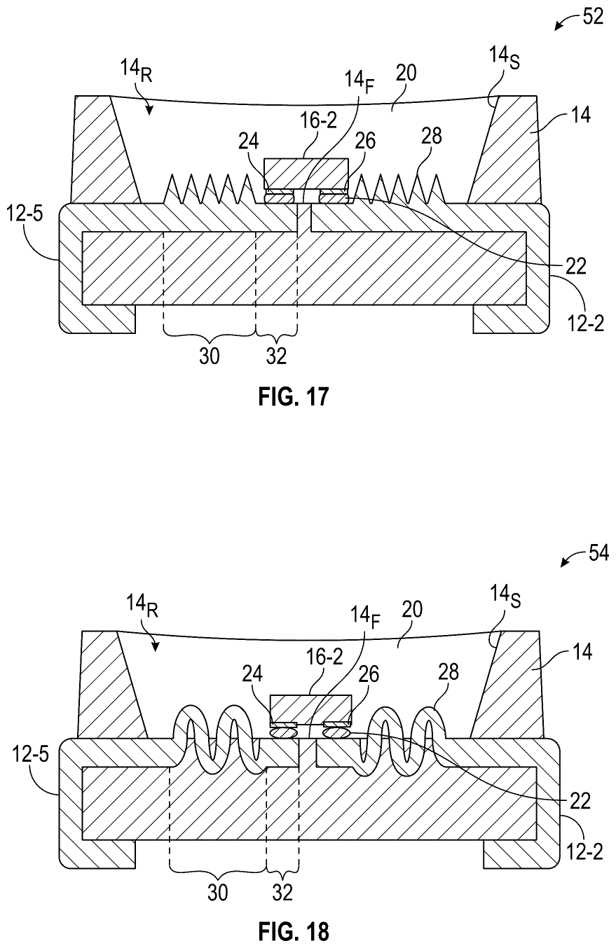

FIG. 17 is a cross-sectional view of an LED package 52 that is similar to the LED package 10 of FIGS. 1B and 1C for indoor applications. Since moisture ingress is less of a concern for indoor use, the leads 12-2, 12-5 may exit the housing 14 without multiple bends, and the overall LED package 52 may have a lower profile than the LED package 10 of FIGS. 1B and 1C. As illustrated, the features 28 are provided for increased adhesion with the encapsulant 20 and for mitigation of reflow of the chip bonding material 22 in a similar manner as described above for FIGS. 1B and 1C.

FIG. 18 is a cross-sectional view of an LED package 54 that is similar to the LED package 40 of FIG. 3 for indoor applications. As described for FIG. 17, the leads 12-2, 12-5 may exit the housing 14 without multiple bends and the overall LED package 54 may have a lower profile than the LED package 40 of FIG. 3. As illustrated, the features 28 are provided for increased adhesion with the encapsulant 20 and for mitigation of reflow of the chip bonding material 22 in a similar manner as described above for FIG. 3.

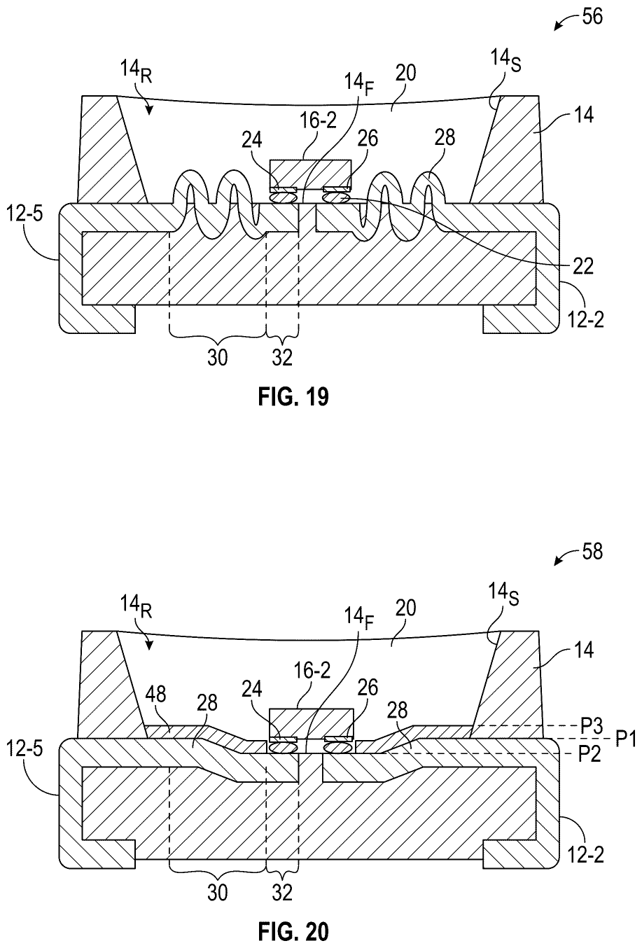

FIG. 19 is a cross-sectional view of an LED package 56 that is similar to the LED package 42 of FIG. 4 for indoor applications. As described for FIG. 17, the leads 12-2, 12-5 may exit the housing 14 without multiple bends, and the overall LED package 56 may have a lower profile than the LED package 42 of FIG. 4. As illustrated, the features 28 are provided for increased adhesion with the encapsulant 20 and for mitigation of reflow of the chip bonding material 22 in a similar manner as described above for FIG. 4.

FIG. 20 is a cross-sectional view of an LED package 58 that is similar to the LED package 46 of FIG. 6 for indoor applications. As described for FIG. 17, the leads 12-2, 12-5 may exit the housing 14 without multiple bends, and the overall LED package 58 may have a lower profile than the LED package 46 of FIG. 6. While the coating 48 is illustrated in FIG. 20, the coating 48 may be omitted in a similar manner as described above for FIG. 5. As illustrated, the features 28 are provided for increased adhesion with the encapsulant 20 and for mitigation of reflow of the chip bonding material 22 in a similar manner as described above for FIGS. 5 and/or 6.

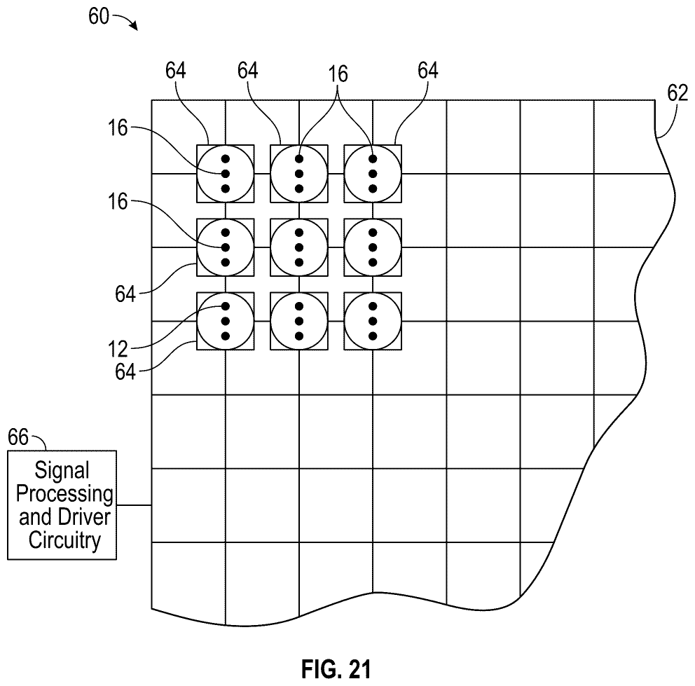

FIG. 21 is a schematic diagram of a portion of an LED display 60, that is, for example, an indoor and/or outdoor display screen comprising, in general terms, a display panel including a PCB 62 carrying a large number of surface-mount devices (SMDs) 64 arranged in rows and columns, each SMD 64 defining a pixel. The SMDs 64 may comprise LED packages with LED chips 16 and lead frame structures as described above for any of the embodiments shown in FIGS. 1A-20. The LED display 60 may further include signal processing and driver circuitry 66 electrically coupled to the PCB 62. In FIG. 21, the signal processing and driver circuitry 66 is illustrated in schematic view. In certain embodiments, the signal processing and driver circuitry 66 may reside on a backside of the PCB 62 opposite the SMDs 64. In other embodiments, the signal processing and driver circuitry 66 may be located in other portions of the LED display 60. The SMDs 64 are electrically connected to electrical connections such as traces or pads on the PCB 62 in a manner similar to FIG. 1C. In this regard, the SMDs 64 may respond to appropriate electrical signals from the signal processing and driver circuitry. In certain aspects, the driver PCB 62 may be similar to the board 34 as described above for FIG. 1C. As disclosed above, it is to be appreciated that while FIG. 21 depicts the LED chips 16 in a linear arrangement, in other embodiments, the LED chips 16 may be arranged in different configurations, such as a triangular layout. By forming lead frame structures for the SMDs 64 as described above for any of FIGS. 1A-20, pixels of the LED display 60 may exhibit increased adhesion with encapsulants while mitigating effects of reflow for chip bonding materials when the SMDs 64 are bonded to the driver PCB 62. Accordingly, the LED display 60 may exhibit improved reliability and/or extended operating lifetime compared with conventional LED display screens.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a housing forming a recess with a recess floor;
a lead frame structure within the housing;
one or more LED chips positioned on the lead frame structure and at the recess floor; and
a plurality of features of the lead frame structure, the plurality of features being nonplanar relative to the recess floor and positioned laterally adjacent to mounting areas of the one or more LED chips.

2. The LED package of claim 1, wherein:
the one or more LED chips comprise a first LED chip; and
the lead frame structure comprises a first lead and a second lead, and the first LED chip is flip-chip mounted to the first lead and the second lead with a chip bonding material.

3. The LED package of claim 2, wherein:
the first lead and the second lead each comprise a first region that includes at least one feature of the plurality of features and a second region where the first LED chip is flip-chip mounted.

4. The LED package of claim 3, wherein the second region is devoid of the plurality of features.

5. The LED package of claim 3, wherein at least one other feature of the plurality of features is in the second region.

6. The LED package of claim 2, wherein:
a first feature of the plurality of features is part of the first lead;
the first feature extends parallel to the recess floor along a first plane in the recess; and
the first LED chip is mounted to the first lead along a second plane that is closer to the recess floor than the first plane.

7. The LED package of claim 6, wherein the first lead extends from the first plane to the second plane in an angled manner.

8. The LED package of claim 6, further comprising:
a coating on the first lead and the second lead, the coating extending to a third plane in the recess such that the first plane is between the third plane and the second plane; and
an encapsulant in the recess such that the coating is between the encapsulant and the first lead and the coating is between the encapsulant and the second lead.

9. The LED package of claim 8, wherein the coating comprises an epoxy material.

10. The LED package of claim 1, further comprising an encapsulant in the recess, wherein the encapsulant forms an interface with at least a portion of the plurality of features.

11. The LED package of claim 10, wherein the encapsulant comprises an epoxy material.

12. The LED package of claim 10, wherein the plurality of features extend into the recess and below the recess floor.

13. The LED package of claim 12, wherein a portion of the encapsulant is positioned between a portion of the plurality of features and the recess floor.

14. The LED package of claim 13, wherein a portion of the housing is positioned between another portion of the plurality of features and the recess floor.

15. The LED package of claim 1, wherein the one or more LED chips are mounted to the lead frame structure with a chip bonding material, and the plurality of features form a raised barrier configured to confine the chip bonding material.

16. The LED package of claim 1, wherein the plurality of features form a plurality of rows on the lead frame structure.

17. The LED package of claim 1, wherein the plurality of features form a plurality of islands of the lead frame structure.

18. The LED package of claim 1, wherein the plurality of features form a grid of the lead frame structure.

19. The LED package of claim 1, wherein the plurality of features form a plurality of indentations of the lead frame structure.

20. The LED package of claim 1, wherein at least one feature of the plurality of features forms a primary shape with at least one secondary shape formed along a side of the primary shape.

21. The LED package of claim 1, wherein at least two features of the plurality of features form a wicking cavity between top surfaces of the at least two features and underlying portions of the lead frame structure.

22. A lighting device comprising:
a board; and
a light-emitting diode (LED) package mounted on the board, the LED package comprising:
a housing forming a recess with a recess floor;
a lead frame structure within the housing;
one or more LED chips positioned on the lead frame structure and at the recess floor; and
a plurality of features of the lead frame structure, the plurality of features being nonplanar relative to the recess floor and positioned laterally adjacent to mounting areas of the one or more LED chips.

23. The lighting device of claim 22, further comprising signal processing and driver circuitry electrically coupled to the board, wherein the board is a printed circuit board (PCB) of an LED display.

24. The lighting device of claim 22, wherein the LED package is coupled with the board by solder material between the lead frame structure and the board.

25. The lighting device of claim 22, wherein the one or more LED chips comprises at least three LED chips in a linear arrangement.

26. The lighting device of claim 22, wherein:
the one or more LED chips are mounted to the lead frame structure with a chip bonding material;
the LED package is mounted to the board with a package bonding material; and
the plurality of features form a raised barrier configured to confine the chip bonding material during formation of the package bonding material.
